(19) United States
(12) Patent Application Publication
(10) Pub. No.: US 2020/0335968 A1
(43) Pub. Date: Oct. 22, 2020

(54) CURRENT INTERRUPTING DEVICE AND TRANSISTOR SELECTING METHOD

(71) Applicant: KABUSHIKI KAISHA TOSHIBA, Minato-ku (JP)

(72) Inventors: Yusuke HAYASHI, Yokohama (JP); Kazuto Takao, Tsukuba (JP); Tatsunori Sakano, Shinagawa (JP); Kentaro Ikeda, Kawasaki (JP); Masahiro Koyama, Shinagawa (JP); Hongliang Su, Kawasaki (JP)

(73) Assignee: KABUSHIKI KAISHA TOSHIBA, Minato-ku (JP)

(21) Appl. No.: 16/818,531

(22) Filed: Mar. 13, 2020

(30) Foreign Application Priority Data
Apr. 22, 2019 (JP) 2019-081127

(51) Int. Cl. H02H 9/02; H02H 9/04; G01R 19/00

(52) U.S. Cl. CPC H02H 9/025; G01R 19/0084; H02H 9/04

(57) ABSTRACT

A current interrupting device has a first transistor that is normally off and that switches whether to interrupt a current path, and a controller that controls a gate voltage of the first transistor such that, when no overcurrent flows through the current path, the first transistor is operated in an active region, and when an overcurrent flows through the current path, the first transistor is operated in a saturation region to limit the overcurrent, and then, the current path is interrupted.

### CROSS REFERENCE TO RELATED APPLICATIONS

This application is based upon and claims the benefit of priority from the prior Japanese Patent Application No. 2019-81127, filed on Apr. 22, 2019, the entire contents of which are incorporated herein by reference.

### FIELD

Embodiments described herein relate generally to a current interrupting device and a selecting method of a transistor utilized in the current interrupting device.

### BACKGROUND

Due to the widespread use of renewable energy and storage batteries, electric power networks tend to become more complex, and the current flowing through the current path in the power network is also increasing. A current interrupting device is connected to the current path in the power network so as to prevent electrical equipment from being broken due to a large current flowing in the event of a short-circuit accident.

An MCCB (Molded Case Circuit Breaker, a kind of breakers) and a fuse are generally used for the current interrupting device. The MCCB has problems of requiring a long time (milliseconds level) to cut off a short circuit current of the specification, and of having no guarantee of interruption of the second short circuit current after it is again turned on from the viewpoint of reliability on a mechanical contact. The fuse requires a shorter time (several hundreds of microseconds) to interrupt a current than the MCCB. However, the fuse has problems that a current 10 times or more the rated current is required to melt the fuse, and that the fuse cannot be used again because it is melted. In a complicated electric power network, a semiconductor current interrupting device (called e.g. solid state circuit breaker: SSCB) has attracted attention as a current interrupting device that can be used again and can interrupt a short circuit current at high speed (several microseconds) so that the short-circuit current does not increase.

The current interrupting device can be composed of, for example, a power transistor and an inductor. The inductor is provided to suppress the rise of a surge current (di/dt) flowing through the current path in the event of an accident such as a short circuit. In order to reduce the value of a current to be interrupted in the event of an accident, it is also necessary to increase the size of the inductor, which may hamper size reduction and cost reduction of the current interrupting device. In addition, a power loss increases with an increase in size of the inductor.

### BRIEF DESCRIPTION OF THE DRAWINGS

FIG. 1 is a block diagram showing a schematic configuration of a current interrupting device according to a first embodiment;

FIG. 2 is an IV characteristic diagram of a first transistor;

FIG. 3 is a block diagram showing the current interrupting device shown in FIG. 1 to which a voltage detector and a voltage determination unit are added;

FIG. 4 is a flowchart showing an example of a process of the operation of a controller;

FIG. 5 is a diagram of a circuit used in an experiment;

FIGS. 6A to 6C are waveform diagrams of a gate voltage, a drain current, and a drain to source voltage;

FIG. 7 is a diagram showing a safety operation area (SOA) of the first transistor;

FIG. 8 is a block diagram showing a current interrupting device according to a second embodiment;

FIG. 9 is a diagram of an electric circuit used for a simulation;

FIGS. 10A and 10B are waveform diagrams of a drain current and a drain to source voltage;

FIG. 11 is a block diagram showing a schematic configuration of a current interrupting device provided with a third transistor;

FIG. 12 is a block diagram showing that the third transistor includes n transistors;

FIG. 13 is a flowchart showing a procedure of a process for selecting the first transistor in the current interrupting device according to the first or second embodiment;

FIG. 14 is a diagram showing a relationship between a drain to source voltage and a drain current of SiC-BJT;

FIG. 15 is a diagram showing a relationship between a drain current and an on-resistance of the SiC-BJT;

FIG. 16 is a diagram showing a relationship between a drain to source voltage and a drain current of SiC-JFET; and

FIG. 17 is a diagram showing a relationship between a drain current and an on-resistance of the SiC-JFET.

### DETAILED DESCRIPTION

According to one embodiment, a current interrupting device has a first transistor that is normally off and that switches whether to interrupt a current path, and a controller that controls a gate voltage of the first transistor such that, when no overcurrent flows through the current path, the first transistor is operated in an active region, and when an overcurrent flows through the current path, the first transistor is operated in a saturation region to limit the overcurrent, and then, the current path is interrupted.

### First Embodiment

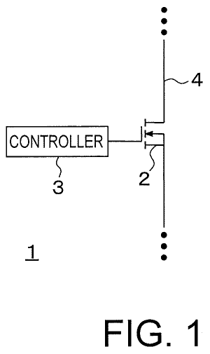

FIG. 1 is a block diagram showing a schematic configuration of a current interrupting device 1 according to the first embodiment. The current interrupting device 1 in FIG. 1 includes a normally-off first transistor 2 and a controller 3.

The first transistor 2 is connected on a predetermined current path 4, and switches whether to interrupt the current path 4. Although the specific location and application of the current path 4 to which the first transistor 2 is connected are not limited, the current path 4 is assumed to have a possibility of having a large current flowing therethrough due to a short-circuit accident.

The first transistor 2 is, for example, a silicon power MOSFET (Metal-Oxide-Semiconductor Field Effect Transistor) or a silicon carbide BJT (Bipolar Junction Transistor). Although not shown in FIG. 1, the first transistor 2 may incorporate a diode connected between the source and drain of the first transistor 2 due to its device structure.

Normally-off means that no current flows between the drain and source of the first transistor 2, when a gate voltage of the first transistor 2 is set to, for example, 0 V, and an off command is given to the first transistor 2.

The controller 3 controls the gate voltage of the first transistor 2. More specifically, the controller 3 controls the gate voltage of the first transistor 2 such that, when no overcurrent flows through the current path 4, the first transistor 2 is operated in an active region, and when a situation such as a short-circuit accident in which an overcurrent flows through the current path 4 occurs, a fixed gate voltage is applied to the first transistor 2 so as to operate the first transistor 2 in a saturation region and to limit a current due to the accident, and after the current due to the accident is limited, the current path 4 is cut off. The controller 3 may be composed of, for example, a semiconductor IC or a discrete circuit.

The controller 3 sets the gate voltage to be the same between when the first transistor 2 is operated in the active region and when the first transistor 2 is operated in the saturation region. More specifically, the controller 3 sets the gate voltage according to a maximum allowable current value that indicates a current allowed to flow through the current path 4 when an overcurrent flows through the current path 4, and applies the set gate voltage to the gate of the first transistor 2 even when no overcurrent flows through the current path 4.

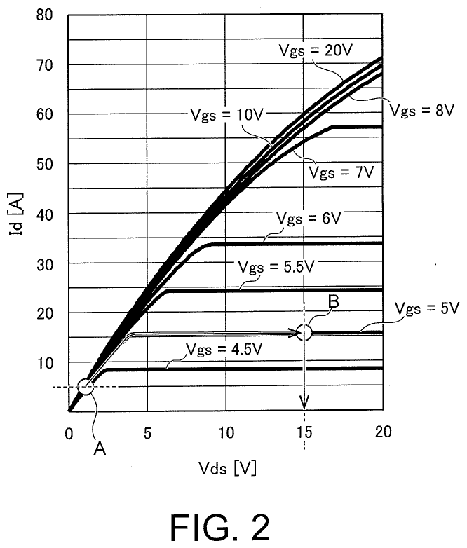

FIG. 2 is an IV characteristic diagram of the first transistor 2. In FIG. 2, the horizontal axis represents a drain to source voltage Vds [V] of the first transistor 2, and the vertical axis represents a drain current Id [A] of the first transistor 2. FIG. 2 shows a plurality of IV curves at different gate voltages Vgs.

The controller 3 according to the present embodiment applies a gate voltage corresponding to a specific IV curve among the plurality of IV curves to the gate of the first transistor 2. For example, if the operating point during normal operation where no overcurrent flows through the current path 4 is point A in FIG. 2, the operating point moves from the point A to a point B on the same IV curve when an overcurrent flows through the current path 4. On the IV curve where the points A and B are located, the gate voltage Vgs is 5 V, the drain current Id in the active region is in the range from 0 A to less than 15 A, and the drain current Id in the saturation region is about 15 A, for example.

Thus, in the present embodiment, the operating point is moved on the same IV curve between during normal operation and during abnormal operation in which overcurrent flows. Therefore, a rapid increase in the drain current Id is less likely to occur during the abnormal operation, and an operation of limiting the current to about 15 A can be performed.

In an actual transistor, it is rare that the slopes of a plurality of IV curves in the active region are similar to one another as shown in FIG. 2, and the slopes of the individual IV curves are often greatly different from one another in the active region. In a transistor in which the slopes of the individual IV curves are greatly different from one another in the active region, when the IV curve with a gate voltage Vgs of 5 V is selected, for example, a desired drain current Id cannot flow, or heat generated in the transistor increases due to an increase in the on resistance of the transistor. Therefore, such transistor may be unusable as the current interrupting device. On the other hand, in the present embodiment, it is assumed that a transistor in which slopes in the active region are similar to one another as shown in FIG. 2 is used as the first transistor 2.

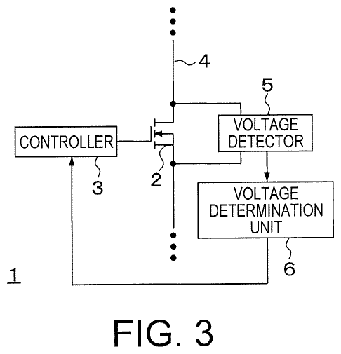

FIG. 3 is a block diagram showing the current interrupting device 1 shown in FIG. 1 to which a voltage detector 5 and a voltage determination unit 6 are added. The voltage detector 5 detects a drain to source voltage of the first transistor 2. The controller 3 assesses whether or not an overcurrent flows through the current path 4 based on the voltage detected by the voltage detector 5.

The voltage determination unit 6 determines whether or not the voltage detected by the voltage detector 5 exceeds a predetermined threshold. When the voltage determination unit 6 determines that the voltage exceeds the predetermined threshold, the controller 3 adjusts the gate voltage so as to turn off the first transistor 2. The voltage determination unit 6 may be built in the controller 3.

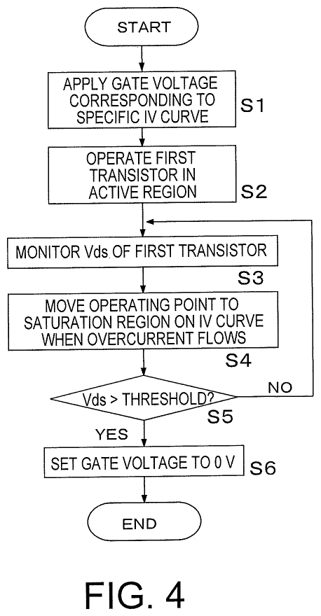

FIG. 4 is a flowchart showing an example of the process of the operation of the controller 3. In an initial state, a gate voltage (for example, 5 V) corresponding to the specific IV curve shown in FIG. 2 is applied to the gate of the first transistor 2 (step S1). As described above, this gate voltage is set according to the maximum allowable current value that indicates a current allowed to flow through the current path 4 when an overcurrent flows through the current path 4.

Setting the gate voltage to 5 V, for example, means that the first transistor 2 is driven with the gate voltage being reduced in advance. Conventionally in the current interrupting device 1, the gate voltage is increased to about 15 V in order to reduce the on resistance of the transistor as much as possible during normal operation, whereas in the present embodiment, the transistor in which slopes are similar to one another in the active region is driven with the gate voltage being rather reduced to about 5 V during normal operation. When the transistor in which the slopes in the active region are similar to one another is driven with a reduced gate voltage, the current flowing through the current path 4 is limited to the maximum allowable current by saturation characteristics without increasing the on resistance, unlike the conventional current interrupting device 1 in which the on resistance is relatively high when the transistor is driven with the gate voltage being reduced.

When the gate voltage is set to about 5 V, the first transistor 2 operates in the active region during normal operation, and the drain to source voltage Vds of the first transistor 2 is, for example, about 1 to 2 V (step S2).

The voltage detector 5 continuously monitors the drain to source voltage Vds of the first transistor 2 (step S3). When the current flowing through the current path 4 increases due to an accident or the like, the operating point of the first transistor 2 automatically moves from the active region to the saturation region (step S4). In the saturation region, the drain current Id assumes a value during a current limiting operation that is slightly greater than that during normal operation.

The voltage determination unit 6 determines whether or not the drain to source voltage Vds of the first transistor 2 has exceeded a predetermined threshold (step S5). Until the voltage determination unit 6 determines that the drain to source voltage Vds of the first transistor 2 has exceeded the threshold value, the processes in steps S3 and S4 are continued. When a short-circuit accident or the like occurs, the operating point shifts from point A to point B in FIG. 2, so that the drain to source voltage Vds of the first transistor 2 increases rapidly and exceeds the threshold. When it is determined that the drain to source voltage Vds has exceeded the threshold, the controller 3 sets the gate voltage to 0 V and turns off the first transistor 2 (step S6).

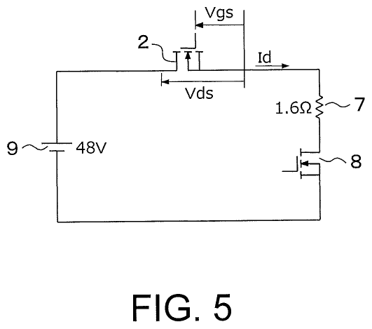

The inventor of the present invention conducted an experiment for causing the first transistor 2 to operate in the active region during normal operation, and to operate in the saturation region during abnormal operation in which an overcurrent flows. FIG. 5 is a diagram of a circuit used in the experiment. FIG. 5 shows a circuit in which a 48 V DC power supply 9 is connected to a circuit in which a first transistor 2, a 1.6Ω resistor 7 for simulating a short circuit current, and a short circuit simulation switch 8 are connected in series. The circuit shown in FIG. 5 does not have a function of detecting the drain to source voltage of the first transistor 2 to control the gate voltage.

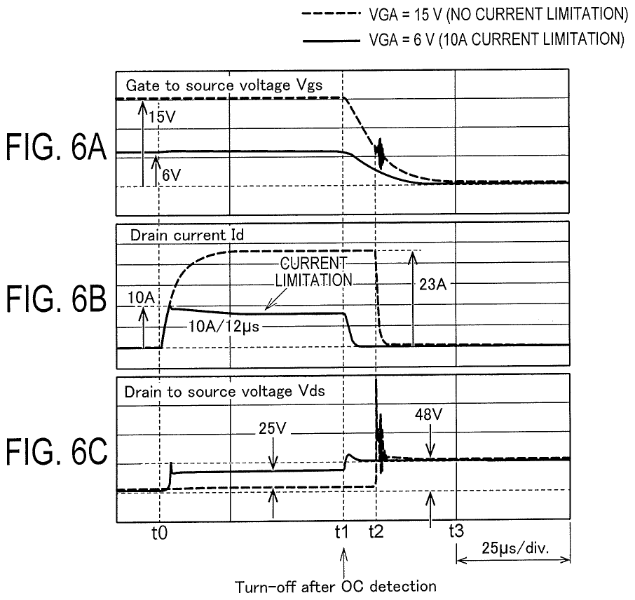

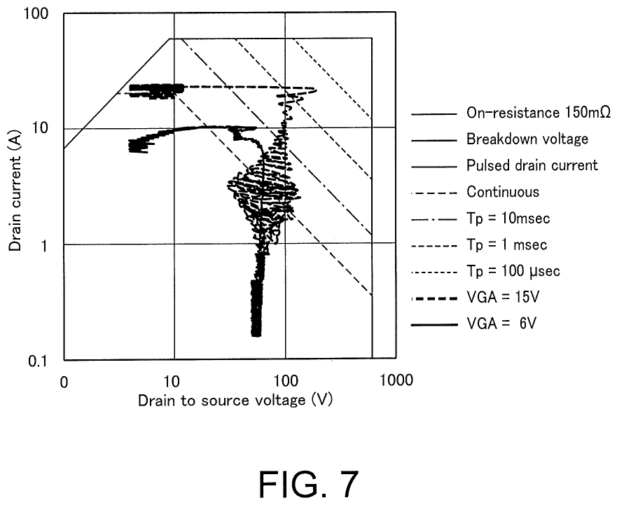

FIGS. 6A to 6C are diagrams showing waveforms of drain current Id and drain to source voltage Vds when the short circuit simulation switch 8 is turned on to cause a short-circuit state with the gate voltage of the first transistor 2 being set to 15 V or 6 V, and then, the gate voltage is changed to 0 V. FIG. 7 is a diagram showing a safety operation region (Safe Operating Area: SOA) of the first transistor 2.

The horizontal axis in FIGS. 6A to 6C represents time. The vertical axis in FIG. 6A represents gate voltage, that is, gate to source voltage Vgs, the vertical axis in FIG. 6B represents drain current Id, and the vertical axis in FIG. 6C represents drain to source voltage Vds.

The dashed line in FIGS. 6A to 6C indicates the waveform of the gate voltage Vgs, the waveform of the drain current Id, and the waveform of the drain to source voltage Vds when the gate voltage is 15 V, and the solid line indicates the waveform of the gate voltage Vgs, the waveform of the drain current Id, and the waveform of the drain to source voltage Vds when the gate voltage is 6 V.

FIGS. 6A to 6C show that, after the short circuit simulation switch 8 is turned on at time t0, the drain current rises to 23 A (the value obtained by dividing 48 V by the sum of 1.6Ω of the resistor 7 and about 0.5Ω of the on resistance of the first transistor 2) without being limited, in the case where the gate voltage is 15 V, and the drain current is limited to at most 10 A without rising to 23 A due to the first transistor 2 operating in the saturation region, in the case where the gate voltage is 6 V. FIGS. 6A to 6C show that the gate voltage of the first transistor 2 starts to decrease at time t1, and the gate voltage becomes 0 V at time t3. When the gate voltage is 15 V, the drain current Id during the period from time t1 to time t2 is 23 A, and the drain current Id after time t2 is 0 A. The drain to source voltage Vds during the period from time t1 to time t2 is about 0 V, and the drain to source voltage Vds after time t2 is about 48 V. On the other hand, when the gate voltage is 6 V, the drain current Id before time t1 is 10 A, and the drain current Id after time t1 is 0 A. The drain to source voltage Vds before time t1 rises to about 25 V, because the first transistor 2 operates in the saturation region, and the drain to source voltage Vds after time t1 is about 48 V.

The conventional current interrupting device 1 having a gate voltage of 15 V determines that an accident occurs when the drain current Id exceeds 20 A, for example, and decreases the gate voltage to 0 V at time t1 due to a control delay or the like. The current interrupting device in which the gate voltage is set to 6 V determines that an accident occurs when the drain to source voltage Vds exceeds 5 V, for example, and decreases the gate voltage to 0 V at time t1 due to a control delay or the like. The current interrupting device according to the present invention can interrupt an overcurrent caused by a short-circuit accident more quickly than the conventional current interrupting device, because voltage detection is performed faster than current detection, and a potential difference is smaller when the voltage is decreased from 6 V to 0 V than when the voltage is decreased from 15 V to 0 V.

FIG. 7 is a diagram showing a safety operation region (Safe Operating Area: SOA) of the first transistor 2. In FIG. 7, the horizontal axis represents drain to source voltage Vds [V], and the vertical axis represents drain current Id [A]. The dashed line in FIG. 7 indicates a waveform when the gate voltage is 15 V, and the solid line indicates a waveform when the gate voltage is 6 V. As shown in FIG. 7, the waveform range is narrower when the gate voltage is 6 V than when the gate voltage is 15 V, which indicates that more safety operation is achieved when the gate voltage is 6 V.

As described above, in the current interrupting device 1 according to the first embodiment, the normally-off first transistor 2 is operated in an active region on a specific IV curve during normal operation, and is operated in a saturation region on the same IV curve during abnormal operation in which overcurrent flows. Therefore, a possibility of a rapid increase in the drain current Id during the abnormal operation is eliminated, and thus, it is unnecessary to provide a large-sized inductor for suppressing a current increase rate (di/dt) of the drain current Id that increases during the abnormal operation. Therefore, the current interrupting device 1 can be reduced in size, and because power loss due to the inductor does not occur, power efficiency can be improved.

In particular, the current interrupting device 1 according to the present embodiment selects a specific IV curve according to the maximum allowable current value that indicates a current allowed to flow through the current path 4 during the abnormal operation, and applies the gate voltage corresponding to the selected IV curve to the gate of the first transistor 2 also during normal operation. When the transistor in which the slopes in the active region are similar to one another as shown in FIG. 2 is operated at a gate voltage reduced in advance corresponding to the selected IV curve, a rapid increase in the drain current Id during the abnormal operation can be suppressed without increasing heat generated in the transistor.

### Second Embodiment

In a current interrupting device 1 according to the second embodiment, a normally-on second transistor is cascode connected to a normally-off first transistor 2.

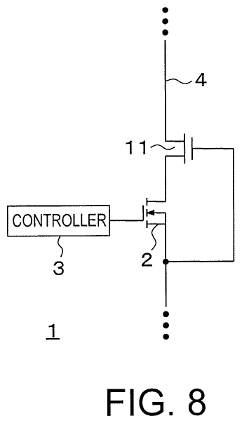

FIG. 8 is a block diagram of the current interrupting device 1 according to the second embodiment. The current interrupting device 1 in FIG. 8 has a configuration obtained by newly adding a normally-on second transistor 11 to the current interrupting device 1 in FIG. 1. The second transistor 11 is cascode connected to the first transistor 2. The gate of the second transistor 11 is connected to the source of the first transistor 2. Normally-on means that, when 0 V is applied to the gate voltage of the second transistor 11, the drain current Id flows, and when a negative voltage (for example, −15 V) is applied to the gate voltage, no current flows. The second transistor 11 is, for example, a SiC-JFET (Junction Field Effect Transistor).

The breakdown voltage of the second transistor 11 is greater than the breakdown voltage of the first transistor 2. When a large voltage is applied between the drain of the second transistor 11 and the source of the first transistor 2, a voltage exceeding the breakdown voltage of the first transistor 2 is prevented from being applied between the drain and source of the first transistor 2, and a voltage that cannot be covered by the breakdown voltage of the first transistor 2 is applied between the drain and source of the second transistor 11. Thus, the breakdown voltage can be increased as compared with the current interrupting device 1 according to the first embodiment.

Like the controller 3 in FIG. 1, the controller 3 in the current interrupting device 1 in FIG. 8 sets the gate voltage such that, during normal operation, the first transistor 2 is operated in an active region, and during abnormal operation in which an overcurrent flows, the first transistor 2 is operated in a saturation region. More specifically, the gate voltage is set based on a specific IV curve by which the drain current Id having the maximum allowable current value indicating a current allowed to flow during abnormal operation flows. As a result, the operating point moves on the IV curve between when normal operation is performed and when abnormal operation is performed, so that a possibility of a rapid rise in the drain current Id during abnormal operation is eliminated.

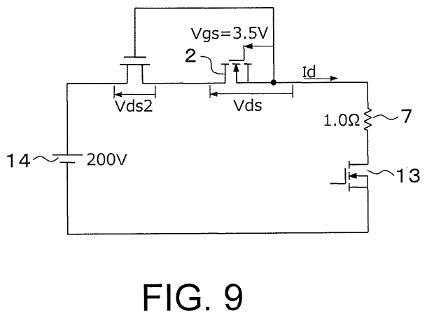

The inventor of the present invention verified the characteristics of the current interrupting device 1 in FIG. 8 by simulation. FIG. 9 is a diagram of a circuit used for the simulation. FIG. 9 shows a circuit in which a 200 V DC power supply 14 is connected to a circuit in which the first transistor 2 and the second transistor 11 which are cascode connected, a 1.0Ω resistor 12 for simulating a short circuit current, and a short circuit simulation switch 13 are connected in series.

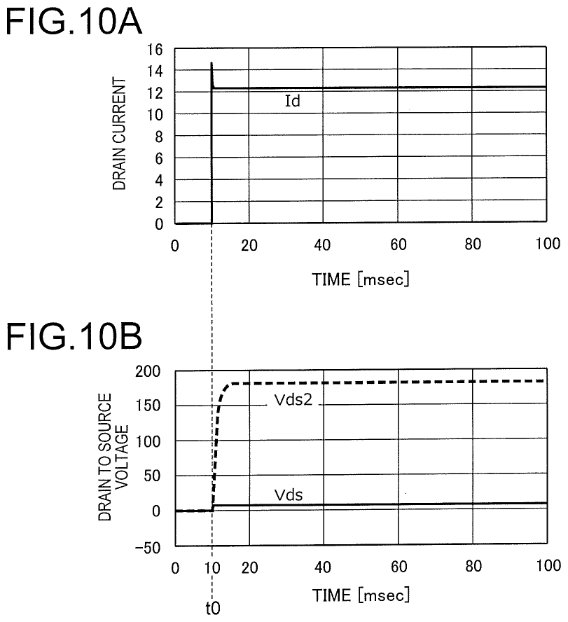

FIGS. 10A and 10B are diagrams showing a simulation result of the circuit in FIG. 8. The horizontal axis in FIG. 10A and FIG. 10B represents time [msec: milliseconds]. The vertical axis in FIG. 10A represents drain current Id of the first transistor 2 and the second transistor 11, and the vertical axis in FIG. 10B represents drain to source voltage Vds of the first transistor 2 and drain to source voltage Vds2 of the second transistor 11. The dashed line in FIG. 10B indicates the waveform of the normally-on transistor (second transistor 11), and the solid line indicates the waveform of the normally-off transistor (first transistor 2).

FIGS. 10A and 10B show waveforms in the case where the gate voltage of the first transistor 2 is constantly set to 3.5 V after time 0, and the short circuit simulation switch 13 is turned on to cause a short-circuit state at time t0=10 msec.

In this example, since the gate voltage of the first transistor 2 is reduced to 3.5 V, even if the short circuit simulation switch 13 is turned on to cause a short-circuit state, the short circuit current of 200 A (=200 V/1Ω) does not flow, and the drain current Id of the first transistor 2 is about 12 A.

After time t0, a voltage of about 200 V is applied between the drain of the second transistor 11 and the source of the first transistor 2. However, as shown in FIG. 10B, only a voltage of about 10 V is applied between the drain and source of the first transistor 2, and the remaining 190 V is applied between the drain and source of the second transistor 11. After t0 where an accident is simulated, the current flowing through the first transistor 2 and the second transistor 11 increases, but the current is limited to 12 A due to the gate voltage of the first transistor 2 being reduced to 3.5 V, so that the first transistor 2 operates in the saturation region. Since the first transistor 2 operates in the saturation region, the drain to source voltage Vds increases. However, at the timing at which the drain to source voltage Vds reaches 10 V, −10 V is applied to the gate voltage of the second transistor 11, and the second transistor 11 is turned off. Since an element having a high breakdown voltage is used for the second transistor 11, 190 V except for 10 V applied to the first transistor 2 is applied to the second transistor 11.

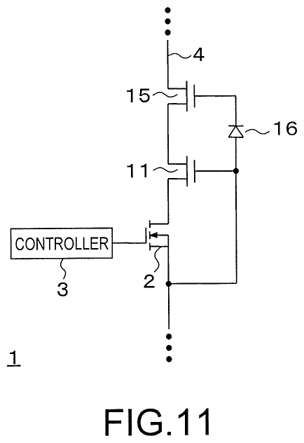

When the breakdown voltage is insufficient with only one second transistor 11, a current interrupting device 1 in which a third transistor is further cascode connected to the second transistor 11 as shown in a circuit diagram in FIG. 11 may be provided.

The current interrupting device 1 in FIG. 11 includes a third transistor 15 that is cascode connected to the second transistor 11, and a diode (rectifier element) 16. The anode of the diode 16 is connected to the gate of the second transistor 11, and the cathode is connected to the gate of the third transistor 15.

Like the second transistor 11, the third transistor 15 has a higher breakdown voltage than the first transistor 2. Due to the diode 16 being connected between the gate of the second transistor 11 and the gate of the third transistor 15, when the drain to source voltage Vds is determined by the gate voltage control of the first transistor 2, the gate voltage of the second transistor 11 is also determined, and the gate voltage of the third transistor 15 can also be determined. Therefore, it is not necessary to individually control the gate voltage of the second transistor 11 and the gate voltage of the third transistor 15, whereby the control of the second transistor 11 and the third transistor 15 is facilitated.

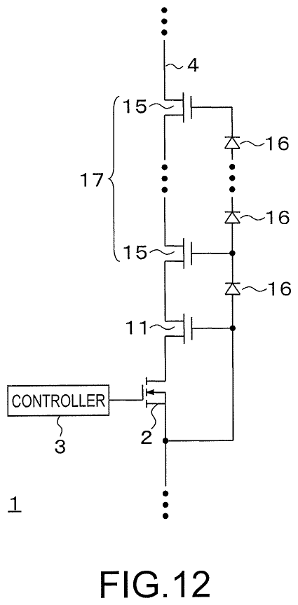

FIG. 11 shows an example in which a single third transistor 15 is connected. However, the third transistor 15 may include a transistor group 17 including n (n is an integer of 2 or more) cascode-connected transistors as shown in FIG. 12. As the value of n is greater, the breakdown voltage of the current interrupting device 1 can be further increased. Also, diodes 16 are connected between the gates of the n transistors in the transistor group 17 with their orientations aligned. Thus, if the source voltage of the first transistor 2 is determined, the gate voltage of the second transistor 11 and the gate voltages of all the n transistors in the transistor group 17 constituting the third transistor 15 can be determined, whereby it is unnecessary to individually control the gate voltages of the n transistors in the transistor group 17.

Note that the current interrupting device 1 shown in FIGS. 8, 11, and 12 may include a voltage detector 5 and a voltage determination unit 6 similar to those in FIG. 3.

As described above, the current interrupting device 1 according to the second embodiment is provided with the second transistor 11 cascode connected to the first transistor 2, thereby being capable of increasing the breakdown voltage, as compared to the current interrupting device provided with only the first transistor 2. Therefore, a possibility in which a voltage exceeding the breakdown voltage of the first transistor 2 is applied between the drain and source of the first transistor 2 can be eliminated. In addition, since the gate of the second transistor 11 is connected to the source of the first transistor 2, it is unnecessary to control the gate voltage of the second transistor 11, and the operation of the controller 3 may not become complicated even if the second transistor 11 is provided.

Further, when the third transistor 15 is further cascode connected to the second transistor 11, the breakdown voltage can be further increased as compared with the case where the third transistor 15 is not provided. When the diode 16 is connected between the gate of the third transistor 15 and the gate of the second transistor 11, it is not necessary to control the gate voltage of the third transistor 15. Further, when the number of transistors of the third transistor 15 is adjusted, the breakdown voltage can be adjusted according to the applied voltage.

### Third Embodiment

The third embodiment described below relates to a procedure of a process for selecting the first transistor 2 in the current interrupting device 1 according to the first or second embodiment.

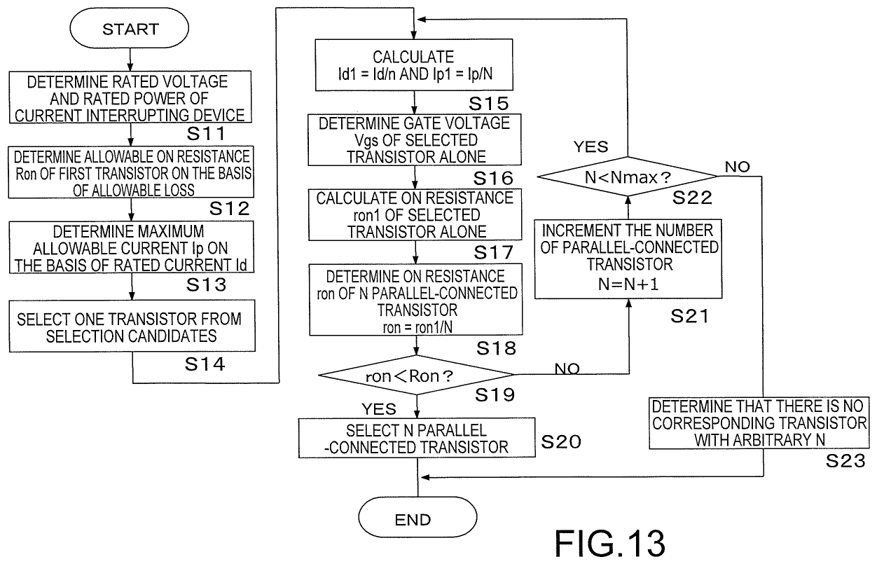

FIG. 13 is a flowchart showing the procedure of the process for selecting the first transistor 2 in the current interrupting device 1 according to the first or second embodiment. First, a rated voltage Vin and rated power Pout of the current interrupting device 1 are determined (step S11). Here, as an example, Vin is 384 V and Pout is 5,000 W.

Next, the allowable on-resistance of the first transistor 2 that is a semiconductor interrupting element is determined based on an allowable loss (step S12). Here, the allowable loss is 0.15%, and the allowable on resistance Ron is 44.2 mΩ as an example.

Next, the maximum allowable current Ip is determined based on the rated current Id (step S13). Here, as an example, the rated current Id is 13 A, and the maximum allowable current Ip is 19.5 A which is 150% of the rated current Id. The rated current value is obtained by dividing the rated power by the rated voltage (13 A≈5000/384).

Next, one transistor is selected from selection candidates for the first transistor 2 (step S14). A rated current Id1 and a maximum allowable current Ip1 of the selected transistor are calculated with respect to N, where N is the number of parallel-connected transistors in the first transistor 2 (step S15). Id1 and Ip1 are respectively represented by Id1=Id/N and Ip1=Ip/N.

Next, the gate voltage Vgs of the transistor selected in step S14 alone is determined (step S16). Next, the on resistance ron1 of the transistor selected in step S14 alone is determined (step S17).

Next, the on resistance ron of the N parallel-connected transistors is determined (step S18). The ron is represented by ron=ron1/N.

Next, it is determined whether or not the on resistance ron is less than an allowable on-resistance Ron (step S19). If ron<Ron, the transistor selected in step S14 is selected as the first transistor 2, and N at that time is selected as the number of parallel-connected transistors (step S20). Then, the process ends.

If ron≥Ron, it is determined that the number of the parallel-connected transistors is inadequate, and the value of N is incremented by 1 (step S21). Next, it is determined whether or not N is less than the maximum limit value Nmax (step S22). If N<Nmax, it is determined that there is no corresponding transistor (step S23), and the process ends. If N<Nmax, the processes after step S15 are repeated.

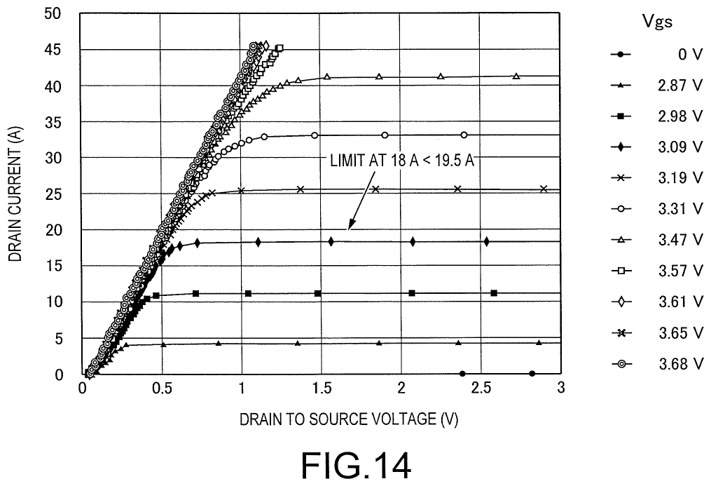

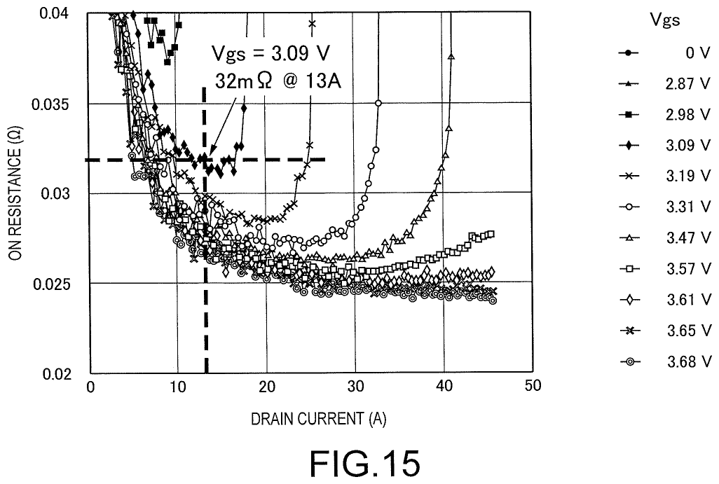

Hereinafter, an example of selecting a desired BJT from SiC-BJTs as the first transistor 2 will be described with reference to the flowchart in FIG. 13. FIGS. 14 and 15 are diagrams showing static characteristics of SiC-BJT. In FIG. 14, the horizontal axis represents drain to source voltage [V], and the vertical axis represents drain current [A]. In FIG. 15, the horizontal axis represents drain current [A], and the vertical axis represents on-resistance [Ω].

In step S14 in FIG. 13, a BJT having the characteristics shown in FIG. 14 is selected, for example. In step S16 in FIG. 13, the gate voltage Vgs is determined to be 3.09 V, for example. When the gate voltage Vgs is determined to be 3.09 V, the on-resistance ron1 of the BJT is 32 mΩ from FIG. 15 (step S17). As shown in FIG. 14, the current is limited at Ip1=18 A. The on resistance ron1 is less than the allowable on resistance 44.2 mΩ (step S19), and the selected BJT is selected as the first transistor 2 (step S20).

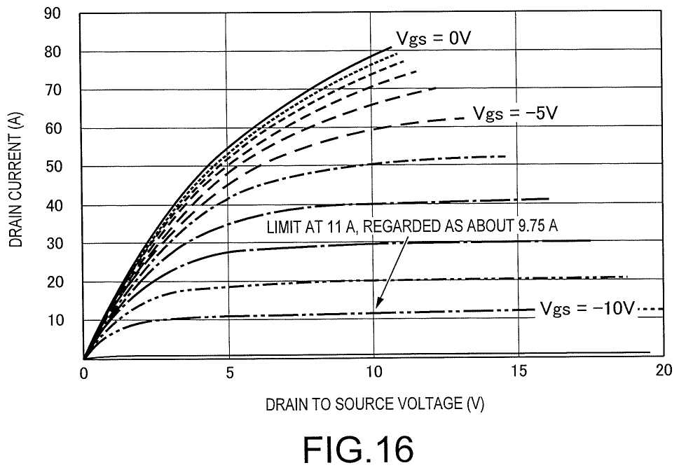

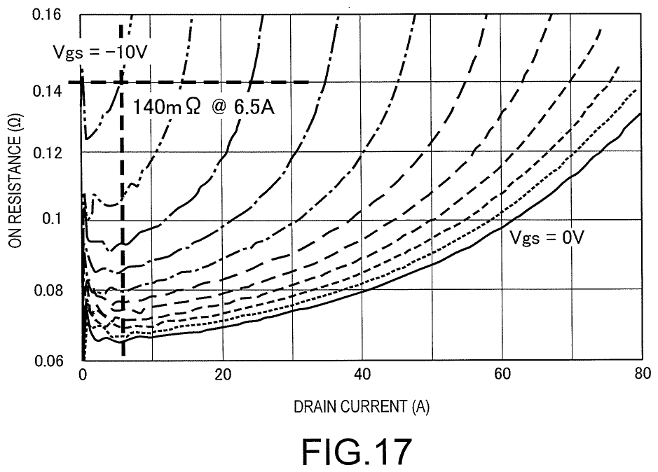

FIGS. 16 and 17 are diagrams showing static characteristics of SiC-JFET. In FIG. 16, the horizontal axis represents drain to source voltage [V], and the vertical axis represents drain current [A]. In FIG. 17, the horizontal axis represents drain current [A], and the vertical axis represents on-resistance [Ω].

In step S14 in FIG. 14, one of the JFETs is selected. When N=2, Id1 is 6.5 A and Ip1 is 9.75 A. In this JFET, a negative voltage is applied to the gate, and therefore, the gate voltage Vgs determined in step S16 in FIG. 14 is −10 V. As shown in FIG. 16, the current is limited at Ip1=11 A, and the on resistance ron1 becomes 140 mΩ at the rated current Id1 of 6.5 A (step S17). This on resistance ron1 is larger than the allowable on resistance 44.2 mΩ and is not suitable. Although values other than 2 are examined for N, a value of N that satisfies the condition is not found, and thus, SiC-JFET is not adopted.

As described above, in the third embodiment, upon selecting the first transistor 2, a transistor having an on-resistance less than the allowable on resistance is selected as the first transistor 2 while varying N, where N is the number of parallel-connected selection candidate transistors. By selecting transistors in which slopes in an active region are similar to one another as candidates for the first transistor 2, it is possible to select a transistor that satisfies the allowable on resistance even when the gate voltage Vgs is reduced. Therefore, even if the first transistor 2 is composed of N parallel-connected transistors, the first transistor 2 can be operated in an active region on a specific IV curve during normal operation and can be operated in a saturation region on the same IV curve during abnormal operation in which an overcurrent flows, if the parallel-connected transistors have similar electrical characteristics.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A current interrupting device comprising:
a first transistor that is normally off and that switches whether to interrupt a current path; and
a controller that controls a gate voltage of the first transistor such that, when no overcurrent flows through the current path, the first transistor is operated in an active region, and when an overcurrent flows through the current path, the first transistor is operated in a saturation region to limit the overcurrent, and then, the current path is interrupted.

2. The current interrupting device according to claim 1,
wherein the controller sets the gate voltage to be equal between when the first transistor is operated in the active region and when the first transistor is operated in the saturation region.

3. The current interrupting device according to claim 1,
wherein the controller sets the gate voltage depending on a maximum allowable current value that indicates a current allowed to flow through the current path when an overcurrent flows through the current path.

4. The current interrupting device according to claim 1, further comprising a voltage detector that detects a voltage between a drain and a source of the first transistor,
wherein the controller determines whether an overcurrent flows through the current path based on a voltage detected by the voltage detector.

5. The current interrupting device according to claim 4, further comprising
a voltage determination unit that determines whether the voltage detected by the voltage detector exceeds a predetermined threshold,
wherein the controller adjusts the gate voltage so as to turn off the first transistor and interrupt the current path, when the voltage determination unit determines that the voltage detected by the voltage detector exceeds the predetermined threshold.

6. The current interrupting device according to claim 1,
wherein the controller moves an operating point on an IV curve indicating a correspondence relation between a drain current and a drain to source voltage of the first transistor at the gate voltage set in advance, between when an overcurrent flows through the current path and when no overcurrent flows through the current path.

7. The current interrupting device according to claim 1, further comprising
a second transistor that is normally on and that is cascode connected to the first transistor,
wherein a gate of the second transistor is connected to a source of the first transistor.

8. The current interrupting device according to claim 7,
wherein a breakdown voltage of the second transistor is higher than a breakdown voltage of the first transistor.

9. The current interrupting device according to claim 7, further comprising:
a third transistor that is normally on and that is cascode connected to the second transistor; and
a rectifier element connected between a gate of the third transistor and a gate of the second transistor.

10. The current interrupting device according to claim 9,
wherein an anode of the rectifier element is connected to the gate of the second transistor, and
a cathode of the rectifier element is connected to the gate of the third transistor.

11. The current interrupting device according to claim 9,
wherein a breakdown voltage of the third transistor is higher than a breakdown voltage of the first transistor.

12. The current interrupting device according to claim 9,
wherein a source of the third transistor is connected to a drain of the second transistor, and
a source of the second transistor is connected to the drain of the first transistor.

13. The current interrupting device according to claim 9,
wherein the third transistor comprises a transistor group including n (n is an integer of 2 or more) cascode-connected transistors, and
a breakdown voltage is adjusted by a value of the n.

14. The current interrupting device according to claim 13,
wherein a source of a transistor at one end of the transistor group including the n transistors is connected to a drain of the second transistor.

15. The current interrupting device according to claim 13,
wherein the rectifier element is individually connected between gates of the n transistors in the transistor group.

16. A transistor selecting method that selects a first transistor in a current interrupting device that comprises the first transistor that is normally off and that switches whether to interrupt a current path, and a controller that controls a gate voltage of the first transistor such that, when no overcurrent flows through the current path, the first transistor is operated in an active region, and when an overcurrent flows through the current path, the first transistor is operated in a saturation region to limit the overcurrent, and then, the current path is interrupted, the method comprising:
determining a rated voltage and a rated power of the current interrupting device;
determining an allowable on-resistance of the first transistor based on an allowable loss;
determining a maximum allowable current based on a rated current according to the rated power and the rated voltage;
selecting one of a plurality of transistors that are selection candidates of the first transistor;
calculating a rated current and a maximum allowable current of the selected transistor alone with a number of the selected transistor to be connected in parallel being defined as N (N is an integer of 1 or more);
determining a gate voltage of the selected transistor alone based on the rated current and the maximum allowable current;
determining an on-resistance of the selected transistor alone;
determining an on-resistance of the N parallel-connected selected transistor;
assessing whether the on-resistance of the N parallel-connected selected transistor is smaller than the allowable on-resistance; and
selecting the N parallel-connected selected transistor as the first transistor, when the on-resistance of the N parallel-connected selected transistor is assessed to be smaller than the allowable on-resistance.

17. The transistor selecting method according to claim 16, further comprising
increasing a value of the N when it is assessed that the on-resistance of the N parallel-connected selected transistor is not smaller than the allowable on-resistance,
wherein the calculating a rated current and a maximum allowable current of the selected transistor alone, the determining a gate voltage of the selected transistor alone, the determining an on-resistance of the selected transistor alone, the determining an on-resistance of the N parallel-connected selected transistor, and the assessing whether the on-resistance of the N parallel-connected selected transistor is smaller than the allowable on-resistance are repeated until the value of the N reaches a predetermined reference value.
